(19) United States
(12) Patent Application Publication
(10) Pub. No.: US 2025/0260303 A1
(43) Pub. Date: Aug. 14, 2025

(54) SWITCH HAVING AN ELECTRONIC TRIP UNIT

(71) Applicant: Siemens Aktiengesellschaft, München (DE)

(72) Inventors: Martin Müllhofer, Poppenricht (DE); Helmut Dietl, Schönthal - OT Hiltersried (DE); Andreas Fischer, Amberg (DE); Hans Gradl, Teublitz (DE)

(21) Appl. No.: 19/042,062

(22) Filed: Jan. 31, 2025

(30) Foreign Application Priority Data
Feb. 9, 2024 (DE) 10 2024 201 202.5

(51) Int. Cl. H02M 1/00; H02H 3/08; H02M 3/155

(52) U.S. Cl. CPC H02M 1/0045; H02H 3/08; H02M 3/155

(57) ABSTRACT

A switch having an electronic trip unit and a power supply circuit for supplying energy to the electronic trip unit from a monitored circuit is provided. In the switch, the power supply circuit is formed by a linear regulator and a switching regulator. In this case, the linear regulator and the switching regulator are connected in parallel. The switching regulator has a Power Good output and the linear regulator has a Disable input, which are connected to one other. This arrangement requires little effort and, when a power supply is established, results in the output voltage being provided quickly by the linear regulator and the latter is then deactivated via the Disable input when the switching regulator, which operates with less loss, is able to provide the power supply. The switching regulator takes over the power supply automatically without any external additional elements or signalling.

### CROSS-REFERENCE TO RELATED APPLICATIONS

This application claims priority to DE Application No. 10 2024 201 202.5, having a filing date of Feb. 9, 2024, the entire contents of which are hereby incorporated by reference.

### FIELD OF TECHNOLOGY

The following relates to a switch having an electronic trip unit and a power supply circuit for supplying energy to the electronic trip unit from a monitored circuit.

### BACKGROUND

Circuit breakers installed in a circuit provide protection for the circuit which functions similar to a fuse. Protection is provided by monitoring the current flowing through a conductor of the circuit. Typically, in this case, the circuit transmits an electric current or energy flow to an energy sink or a load. The circuit breakers monitor protection parameters for the presence of conditions for interrupting the circuit by opening the switch (this is also referred to as tripping the switch). Such protection functions usually relate to short-circuit current (monitoring of the absolute value of the current) and overcurrent (monitoring for exceedance of current thresholds for predefined periods of time). In addition, provision can be made for triggering which follows more complex criteria in the presence of an arc fault.

Interruption is performed, for example, by contacts of the circuit breaker, which are opened. In contrast to a fuse, it is possible to adjust these protection parameters or response values for a circuit breaker. For adjusting these parameters and for checking the tripping criteria, modern circuit breakers usually have a control unit, which is also referred to as an electronic trip unit (ETU) or as an overcurrent trip unit.

For low-voltage circuits or supply systems, there are various types of circuit breakers, depending on the level of the envisaged electric current in the electrical circuit. Within the context of embodiments of the invention, circuit breakers mean, switches as used in low-voltage installations for currents of from 25 to 6300 amperes. Molded case circuit breakers are especially used for currents of from 63 to 1600 amperes, of from 125 to 630 or 1200 amperes. Air circuit breakers are used for currents of from 630 to 6300 amperes, especially of from 1200 to 6300 amperes. Air circuit breakers are also referred to as ACBs for short and molded case circuit breakers are referred to as MCCBs for short.

Low voltage means voltages of up to 1000 volts AC or 1500 volts DC. Low voltage also means voltages which are greater than extra-low voltage with values of 50 volts AC or 120 volts DC.

### SUMMARY

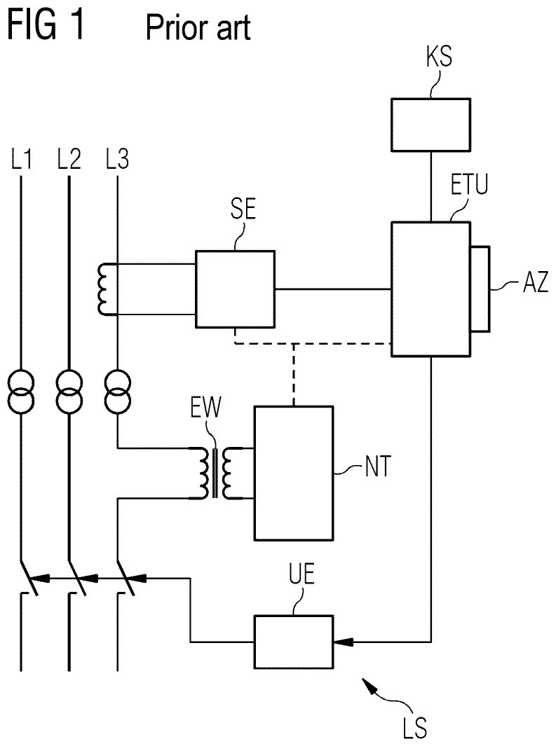

An example of a circuit breaker LS having an electronic trip unit or ETU serving as a control unit is shown in FIG. 1. The circuit breaker is intended to interrupt electrical conductors L1, L2, L3 of an electrical circuit, for example a three-phase AC circuit, wherein the first conductor L1 forms the first phase, the second conductor L2 forms the second phase and the third conductor L3 forms the third phase of the three-phase AC circuit. A neutral conductor may also be additionally provided.

In the example according to FIG. 1, the third conductor L3 is connected to the energy converter EW in such a way that at least a portion of the current, i.e., a partial conductor current, or the entire current of the third conductor flows through the primary side of an energy converter EW. The energy converter EW is usually a transformer with a core. An energy converter EW may also be provided in each phase or in each conductor of the electrical circuit. The secondary side of the energy converter EW is connected to a power supply unit NT which supplies energy, typically in the form of a supply voltage, for the electronic trip unit ETU. Provision is made for a sensor unit SE which is formed by at least one sensor element, e.g., a Rogowski coil, for ascertaining the level of the electric current. In a common design variant, the level of the electric current of each phase conductor or conductor of the electrical circuit is ascertained.

The sensor unit SE is connected to the control unit ETU and transmits the level of the electric current of the conductors L1-L3 of the electrical circuit to the control unit.

The transmitted current values are compared in the electronic trip unit ETU with current limit values and/or current/time period limit values, which form reasons for tripping. If the limit values are exceeded, interruption of the electrical circuit is prompted. This is realized by an interruption unit UE which on one side is connected to the electronic trip unit ETU and on the other side has contacts for interrupting the conductors L1, L2, L3 or further conductors of the electrical circuit. The interruption unit UE in this case receives an interruption signal for opening the contacts.

The electronic trip unit ETU is provided with a display AZ on which values of system-relevant variables can be displayed, e.g., current, voltage, energy, power, phase angle, etc. In this case, these variables are partly measured, partly calculated from measured values. Also depicted is a communication interface KS (e.g., ZigBee, WiFi or BLE radio interface or cable interface, e.g. for LAN cables) via which the acquired system-relevant values can be transmitted e.g., to a monitoring point for display or analysis.

Since the electronic trip unit ETU is supplied with energy from the monitored circuit, it is not active so long as no current to be monitored flows. At the end of this idle state, the electronic trip unit ETU must, firstly, wake up very quickly and, secondly, effectively convert the (limited) available energy.

From IN354091-B, a solution for a switch is known, which uses two regulators (50a, 50b) which are controlled by control logic (60) which in turn receives control commands by a controller (90). The use of the regulators allows the power supply to be adapted to allow the switch to operate quickly when waking up from an idle phase.

An aspect of embodiments of the invention provides an effort-optimized energy supply for an ETU of a circuit breaker, which takes into account requirements for fast operability in a wake-up phase as well as an efficient energy supply during regulation operation.

The aspect is achieved by a switch, e.g., a low-voltage circuit breaker, having an electronic trip unit and a power supply circuit for supplying energy to the electronic trip unit from a monitored circuit. In this switch according to embodiments of the invention, the power supply circuit is formed by a linear voltage regulator—hereinafter referred to as “linear regulator”—and a switching regulator, which are connected in parallel with one other. The switching regulator has a Power Good output and the linear regulator has a Disable input, which are connected to one other.

In most cases, a supply voltage which is lower than the mains voltage being supplied is generated for the ETU of a switch. The mains voltage is thus stepped-down for the power supply. For this configuration, a step-down converter or else a so-called SEPIC converter (SEPIC: Single-Ended Primary-Inductor Converter) can be used as the switching regulator. An embodiment of the invention is also able to be used in scenarios in which the voltage needs to be stepped up. In these scenarios, a step-up converter can, e.g., also be used as the switching regulator.

The arrangement, according to embodiments of the invention, requires little effort and, when a power supply is established, results in the output voltage being provided quickly by the linear regulator and the latter is then deactivated via the Disable input when the switching regulator, which operates with less loss, is able to provide the power supply. The switching regulator takes over the power supply automatically without any external additional elements or signalling.

According to a further development, a diode or a circuit replicating the behaviour of a diode (circuit of the “ideal diode” type) is connected in series with the output of the switching regulator. In this way, influence of typically present output-side capacitive elements of the switching regulator during the voltage conversion by the linear converter and thus a consequently possible delay in establishing the target output voltage is prevented. A corresponding circuit replicating the behaviour of a diode, which is formed, e.g., by at least one switching transistor (MOSFET, etc.), can be configured in such a way and connected to the Power Good output of the switching regulator in such a way that it becomes conductive when a Power Good signal is present.

According to one embodiment, the power supply circuit of the switch according to the invention is configured to supply energy (typically a power supply) to the electronic trip unit or ETU via energy taken from the monitored circuit by an energy converter.

The power supply circuit can contain components for rectification, for filtering or smoothing and for voltage transformation connected in series. In this case, the component or the stage for voltage transformation can then be formed by the linear regulator and the switching regulator.

### BRIEF DESCRIPTION

Some of the embodiments will be described in detail, with reference to the following figures, wherein like designations denote like members, wherein:

FIG. 1: shows a circuit breaker;

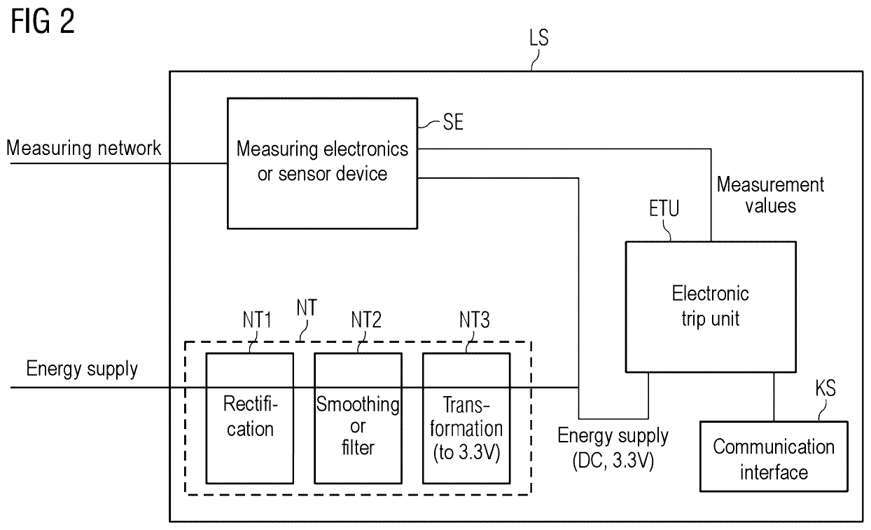

FIG. 2: shows elements of the circuit breaker of FIG. 1;

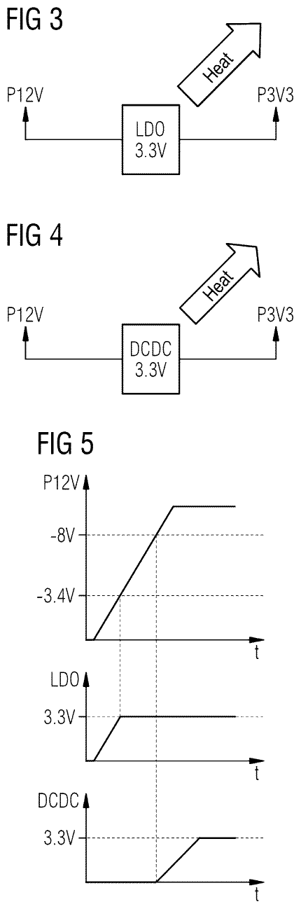

FIG. 3: shows a linear regulator;

FIG. 4: shows a step-down converter;

FIG. 5: shows the behaviour of linear regulator and step-down converter when an output voltage is established;

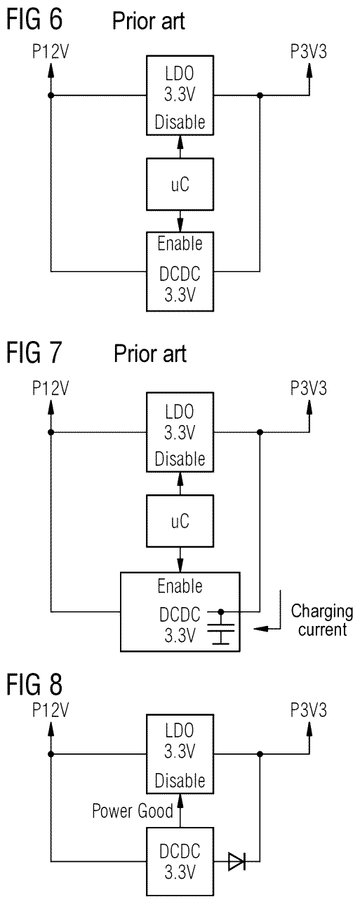

FIG. 6: shows a parallel connection of a linear regulator and a step-down regulator by way of a microcontroller;

FIG. 7: shows the influence of a capacitance of the step-down regulator in a configuration corresponding to FIG. 6;

FIG. 8: shows an inventive arrangement of linear regulator and step-down converter;

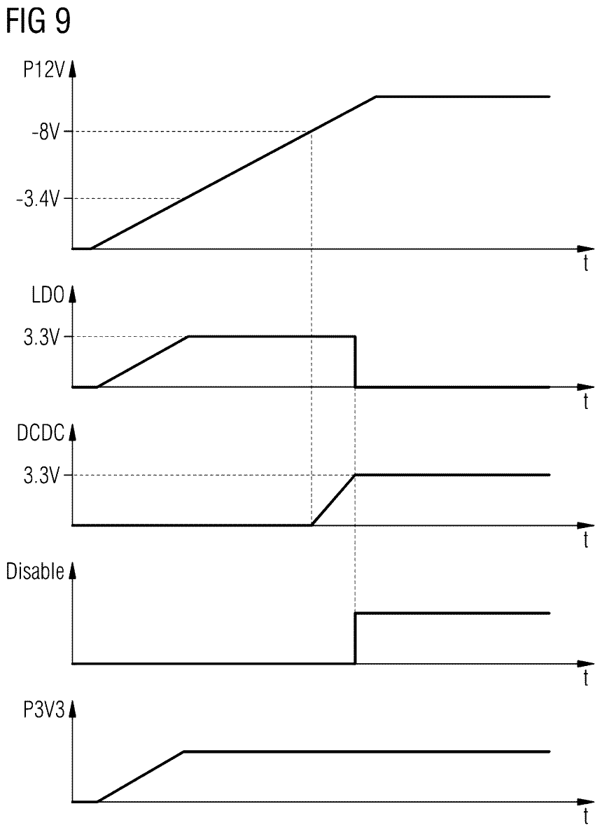

FIG. 9: shows signal curves in an arrangement according to embodiments of the invention; and

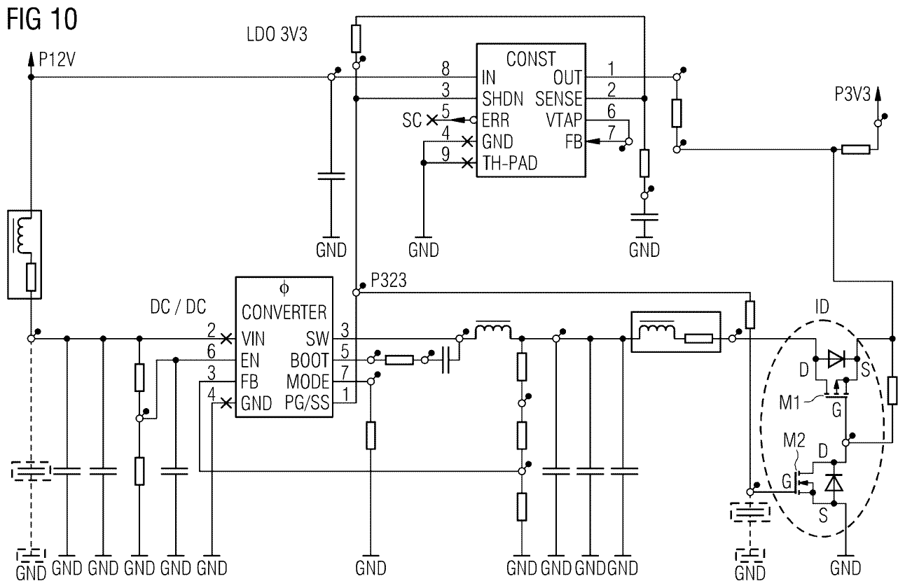

FIG. 10: shows a circuit diagram of an inventive arrangement of linear regulator and step-down converter.

FIG. 2 shows elements of the circuit breaker illustrated in FIG. 1 with a more detailed illustration of the basic design of the power supply unit NT. This is formed by three components NT1-NT3 arranged in series. Typically (in the case of an AC power supply), rectification by NT1 takes place first, then filtering or smoothing by NT2 and finally a transformation of the voltage down to the value of 3.3V suitable for the ETU by NT3.

There are various solutions for the step-down transformation. FIG. 3 shows a linear voltage regulator-also referred to as an LDO or “Low Drop Out”-which steps down the available voltage (e.g., 12V) to the lower voltage of e.g., 3.3V. The advantage of the LDO topology is that the LDO adjusts the desired output voltage already at a slightly higher voltage (above the selected output voltage (3.3V)). The disadvantage, however, is that at higher input voltages the difference between input and output voltage manifests itself in the form of heat as power loss and is therefore no longer available for the actually required output power, i.e., a poor efficiency is accepted.

Another solution is a step-down converter DCDC for voltage conversion, as shown in FIG. 4. The significant advantage here is that the available energy is converted with a high efficiency, i.e., a very good efficiency is achieved.

However, as a disadvantage, it should be noted that a step-down converter requires a significantly longer time to adjust the output voltage and requires a greater difference between input and output voltage.

FIG. 5 shows the behaviour of both converters for the step-down transformation from a 12V voltage to the input value of 3.3V required by the ETU during the wake-up phase of the ETU. The top curve shows the voltage building up at the input of the converter when the circuit breaker LS from FIG. 1 is supplied with energy again via the energy converter EW after a phase in which the circuit has not carried any current. The middle curve illustrates the voltage provided at the output of an LDO; the lower curve illustrates the voltage at the output of a step-down converter DCDC. The target voltage of 3.3V is delivered considerably quicker by the LDO.

To counteract the power loss disadvantage of the LDO, a step-down converter DCDC is combined with an LDO, i.e., in order to combine the advantages of both converters, the linear regulator or LDO and the step-down converter DCDC are connected in parallel. In the start-up phase, the LDO should firstly bring the output voltage to the target value quickly, in order to then be replaced by the step-down converter DCDC with the better efficiency. The switchover from LDO to step-down converter DCDC can be performed by a microprocessor uC, as indicated in FIG. 6. However, this solution first of all has the disadvantage of relatively high effort (additional microprocessor). A further disadvantage is that the step-down converter DCDC has a capacitor in the output, which capacitor constitutes an additional (capacitive) load for the LDO as the voltage is building up (cf. FIG. 7).

According to embodiments of the invention, the switchover after reaching the output voltage of the step-down converter DCDC is therefore performed automatically by a Power Good output which is led to a Disable input at the LDO. An electrical signal (Power Good signal) is applied to the Power Good output if the target output voltage is generated within its tolerance range after the transient response or after the start-up phase. This signal deactivates the LDO via the Disable input. In this case, the switchover is performed without interrupting or decreasing the output voltage. This solution is illustrated in FIG. 8. In addition, a diode or a circuit replicating the diode function is connected downstream of the step-down converter DCDC, which diode or circuit prevents the capacitor in the output of the step-down converter DCDC from being charged during the voltage build-up by the LDO and thus slows the voltage build-up.

FIG. 9 shows signal curves. From top to bottom, the following are illustrated: the voltage at the input of the converter parallel connection, the voltage at the output of the LDO, the voltage at the output of the step-down converter, the signal at the Power Good output of the step-down converter or at the Disable input of the LDO, and the output voltage provided to the ETU. As can be seen in the diagram of FIG. 9, the LDO follows the input voltage almost synchronously and delivers the desired output voltage of 3.3V already after reaching ˜3.4V input voltage. The step-down converter begins to work upward of a voltage of ˜8V. As soon as the desired output voltage is reached, a step-down converter sends a switch-off command to the LDO, whereupon the LDO adjusts the “delivery”. The step-down converter now takes over the 3.3V voltage generation in its entirety.

FIG. 10 shows a more detailed illustration of an inventive parallel connection of an LDO and a step-down converter DCDC. The step-down converter DCDC has a Power Good output PG/SS which is connected to a Disable input SHDN of the LDO. Instead of the downstream diode, located at the output of the step-down converter DCDC is a MOSFET (see FIG. 10) which constitutes an “ideal” diode. The latter has two aspects:
1. Reducing the peak current load (inrush current) of the LDO caused by the capacitive load (output capacitors of the step-down converter DCDC) in the phase of the voltage build-up and
2. Minimizing the on-state losses when the step-down converter DCDC is active, as a result of which a stable output voltage is achieved for different output currents.

The so-called “ideal” diode is a circuit which replicates the behaviour of a diode. Such circuits are known from the conventional art (wherein the behaviour is more or less “ideal” depending on the embodiment). In FIG. 10, this ideal diode ID is formed by two MOSFETs M1 and M2 and is controlled by the Power Good (Disable) signal, for which the Power Good output PG/SS of the step-down converter DCDC is connected to the gate electrode of the transistor M2.

A significant advantage to a solution corresponding to FIG. 6 or FIG. 7 is that the switchover is performed automatically without an additional element (e.g., microprocessor) and without the need for firmware commands. The capacitive load on the LDO during start-up is reduced by the MOSFET circuit.

Only one special case of a solution is described according to embodiments of the invention. This should not be interpreted as limiting. Numerous further configurations which fall within the scope of protection of the application are immediately clear to the person skilled in the art. For example, depending on the scenario, instead of a step-down converter, a SEPIC converter or a step-up converter can be used as the switching regulator.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1. A switch having an electronic trip unit and a power supply circuit for supplying energy to the electronic trip unit from a monitored circuit, in which switch
the power supply circuit is formed by a linear regulator and a switching regulator, wherein
the linear regulator and the switching regulator are connected in parallel,
the switching regulator has a Power Good output,
the linear regulator has a Disable input, and
the Power Good output of the switching regulator is connected to the Disable input of the linear regulator.

2. The switch as claimed in claim 1,
wherein the switching regulator is a step-down converter, a SEPIC converter or a step-up converter.

3. The switch as claimed in claim 1,
wherein a diode or a circuit replicating the behaviour of a diode is connected in series with the output of the switching regulator.

4. The switch as claimed in claim 3,
wherein a circuit replicating the behaviour of a diode is connected in series with the output of the switching regulator, and
the circuit replicating the behaviour of a diode is configured in such a way and connected to the Power Good output of the switching regulator in such a way that the circuit replicating the behaviour of a diode becomes conductive when a Power Good signal is present.

5. The switch as claimed in claim 4,
wherein the circuit replicating the behaviour of a diode is formed by at least one switching transistor.

6. The switch as claimed in claim 5,
wherein the at least one switching transistor is a MOSFET.

7. The switch as claimed in claim 1,
wherein the power supply circuit is configured to supply energy to the electronic trip unit via energy taken from the monitored circuit by an energy converter.

8. The switch as claimed in claim 7,
wherein the power supply circuit contains components for rectification, for filtering or smoothing and for voltage transformation connected in series.

9. The switch as claimed in claim 8,
wherein the component (stage) for voltage transformation is formed by the linear regulator and the switching regulator.

10. The switch as claimed in claim 1,
wherein the switch is a low-voltage circuit breaker.
